(19) United States
(12) Patent Application Publication
(10) Pub. No.: US 2025/0168265 A1
(43) Pub. Date: May 22, 2025

(54) DISPLAY DEVICE INCLUDING ANTENNAE AND ANTENNA CIRCUIT BOARD

(71) Applicants: SAMSUNG DISPLAY CO., LTD., YONGIN-SI (KR); Seoul National University R&DB Foundation, Seoul (KR)

(72) Inventors: Ki Seo KIM, Yongin-si (KR); Jung Suek OH, Seoul (KR); Jae Uk CHOI, Yongin-si (KR); Jeong Taek OH, Seoul (KR); Byeong Jin KIM, Seoul (KR)

(21) Appl. No.: 18/823,135

(22) Filed: Sep. 3, 2024

(30) Foreign Application Priority Data
Nov. 20, 2023 (KR) 10-2023-0160398

(51) Int. Cl. H04M 1/02; G06F 3/041; G06F 3/044; G09G 3/00; G09G 3/32; H01Q 1/24; H01Q 1/52; H01Q 9/06; H01Q 19/30

(52) U.S. Cl. CPC H04M 1/0268; G06F 3/0412; G09G 3/035; G09G 3/32; H01Q 1/243; H01Q 1/526; H01Q 9/065; H01Q 19/30; G06F 3/0443; G06F 2203/04102; G09G 2354/00; H04M 2201/38

(57) ABSTRACT

A display device includes a display panel including a display area and a non-display area at least partially surrounding the display area and including a dielectric film including a protrusion area extending from a portion of the non-display area, and an antenna circuit board connected to the protrusion area. The protrusion area includes a first area in parallel with the non-display area, a bending area extending from the first area and bent toward a rear surface of the display panel to face a side surface direction of the display panel, and a second area extending from the bending area and overlapping the first area at a lower portion of the display panel. The protrusion area further includes a first antenna disposed in a portion of the second area corresponding to the non-display area, and a second antenna overlapping the first antenna in the first area.

### CROSS-REFERENCE TO RELATED APPLICATION

This application claims priority under 35 U.S.C. § 119 to Korean Patent Application No. 10-2023-0160398, filed on Nov. 20, 2023 in the Korean Intellectual Property Office, the contents of which in its entirety are herein incorporated by reference.

### TECHNICAL FIELD

The present disclosure relates to a display device and, more particularly, to a display device including antennae and antenna circuit board.

### DISCUSSION OF THE RELATED ART

As the information society develops, the demand for a diverse assortment of display devices for displaying images has increased. For example, display devices have been applied to various electronic devices such as smartphones, digital cameras, laptop computers, navigation devices, and smart televisions.

A display device included in a mobile electronic device may include an antenna that transmits and receives electromagnetic waves for wireless communication. For example, the display device may include an antenna for 4^{th} generation (4G) mobile communication such as long term evolution (LTE) and 5^{th} generation (5G) mobile communication. A frequency band of electromagnetic waves may be various depending on communication technology, and a shape or a length of the antenna may be changed depending on the frequency band of the electromagnetic waves.

### SUMMARY

A display device includes a display panel including a display area and a non-display area at least partially surrounding the display area and including a dielectric film including a protrusion area extending from a portion of the non-display area, and an antenna circuit board connected to the protrusion area. The protrusion area includes a first area in parallel with the non-display area, a bending area extending from the first area and bent toward a rear surface of the display panel to face a side surface direction of the display panel, and a second area extending from the bending area and overlapping the first area at a lower portion of the display panel. The protrusion area further includes a first antenna disposed in a portion of the second area corresponding to the non-display area, and a second antenna overlapping the first antenna in the first area.

The display panel may have a stack structure that includes a flexible substrate, a lower cover layer disposed below the flexible substrate and including a heat dissipator, a display layer disposed on the flexible substrate, a dielectric film disposed on the display layer, a polarizing film disposed on the dielectric film, and a cover window disposed on the polarizing film. The lower cover layer may include an opening in which the heat dissipator is removed at a portion thereof overlapping the first antenna and the second antenna.

The first antenna and the second antenna may each have a symmetrical dipole antenna structure.

The first antenna and the second antenna may each have a symmetrical slot antenna structure.

The first antenna and the second antenna may each have a Quasi-Yagi structure.

The first antenna and the second antenna may each be array antennas arranged in a 1×N shape (where N is an integer of 2 or more).

A feeding line connected to the first antenna and the second antenna may be disposed in the bending area.

A shield including a conductive metal may be disposed in the bending area, and the shield may be segmented from the first antenna and the second antenna.

The first antenna and the second antenna may each be disposed on a front surface of the dielectric film.

The first antenna and the second antenna may each be disposed on a rear surface of the dielectric film.

The dielectric film may include a touch electrode corresponding to the display area.

A display device includes a display panel including a display area and a non-display area at least partially surrounding the display area and including a flexible substrate including a protrusion area extending from a portion of the non-display area, and an antenna circuit board connected to the protrusion area. The protrusion area includes a first area in parallel with the non-display area, a bending area extending from the first area and bent toward a rear surface of the display panel to face a side surface direction of the display panel, and a second area extending from the bending area and overlapping the first area at a lower portion of the display panel. The protrusion area further includes a first antenna disposed in a portion of the second area corresponding to the non-display area, and a second antenna overlapping the first antenna in the first area.

The display panel may have a stack structure that includes the flexible substrate, a lower cover layer disposed below the flexible substrate and including a heat dissipator, a display layer disposed on the flexible substrate, a polarizing film disposed on the flexible substrate, and a cover window disposed on the polarizing film.

The lower cover layer may include an opening in which the heat dissipator is removed at a portion thereof overlapping the first antenna and the second antenna.

The first antenna and the second antenna may each have a symmetrical dipole antenna structure.

The first antenna and the second antenna may each have a symmetrical slot antenna structure.

The first antenna and the second antenna may each have a Quasi-Yagi structure.

The first antenna and the second antenna are array antennas may each be arranged in a 1×N shape (where N is an integer of 2 or more).

A feeding line connected to the first antenna and the second antenna may be disposed in the bending area.

### BRIEF DESCRIPTION OF THE DRAWINGS

The above and other aspects and features of the present disclosure will become more apparent by describing in detail exemplary embodiments thereof with reference to the attached drawings, in which:

FIGS. 1 and 2 are plan views illustrating a display device according to an exemplary embodiment;

FIGS. 3 and 4 are side views illustrating the display device according to an exemplary embodiment;

FIG. 5 is a schematic cross-sectional view of the display device illustrating a protrusion area of a display panel according to an exemplary embodiment;

FIG. 6 is a plan view illustrating a first antenna and a second antenna according to an exemplary embodiment;

FIG. 7 is a schematic cross-sectional view illustrating a bending area of the protrusion area according to an exemplary embodiment;

FIG. 8 is a graph illustrating characteristics of the first antenna according to an exemplary embodiment;

FIG. 9 is a plan view illustrating a first antenna and a second antenna according to an exemplary embodiment;

FIG. 10 is a graph illustrating characteristics of the first antenna according to an exemplary embodiment;

FIG. 11 is a plan view illustrating a first antenna and a second antenna according to an exemplary embodiment;

FIG. 12 is a schematic cross-sectional view of a display device illustrating an exemplary embodiment in which a feeding line is disposed in the bending area;

FIG. 13 is a diagram illustrating characteristics of the first antenna according to an exemplary embodiment;

FIG. 14 is a plan view illustrating a first antenna and a second antenna according to an exemplary embodiment;

FIG. 15 is a diagram illustrating characteristics of the first antenna according to an exemplary embodiment;

FIG. 16 is a plan view illustrating a first antenna and a second antenna according to an exemplary embodiment;

FIG. 17 is a schematic cross-sectional view of a display device illustrating a protrusion area of a display panel according to an exemplary embodiment;

FIGS. 18 and 19 are side views illustrating a display device according to an exemplary embodiment;

FIG. 20 is a schematic cross-sectional view of a display device illustrating a protrusion area of a display panel according to an exemplary embodiment; and

FIGS. 21 and 22 are a graph and a diagram, respectively, illustrating characteristics of the first antenna according to an exemplary embodiment.

### DETAILED DESCRIPTION OF THE EMBODIMENTS

The present invention will now be described more fully hereinafter with reference to the accompanying drawings, in which exemplary embodiments of the invention are shown. This invention may, however, be embodied in different forms and should not necessarily be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers may indicate the same components throughout the specification and the drawings.

It will be understood that, although the terms “first,” “second,” etc. may be used herein to describe various elements, these elements should not necessarily be limited by these terms. These terms are used to distinguish one element from another element. For instance, a first element discussed below could be termed a second element without departing from the teachings of the present invention. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Hereinafter, specific embodiments will be described with reference to the accompanying drawings.

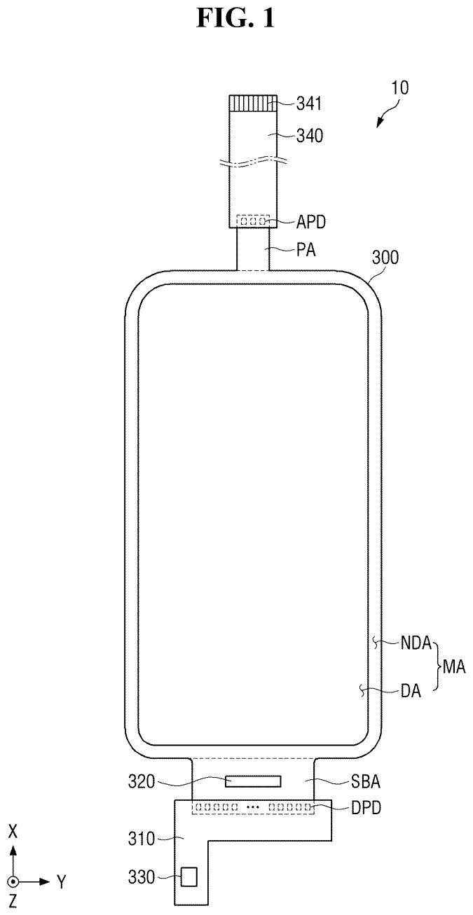

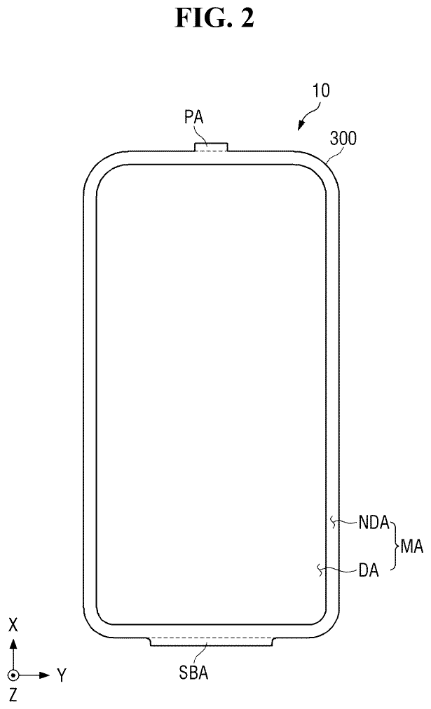

FIGS. 1 and 2 are plan views illustrating a display device according to an exemplary embodiment.

Referring to FIGS. 1 and 2, a display device 10, according to an exemplary embodiment, may be applied to mobile electronic devices such as mobile phones, smartphones, tablet personal computers (PCs), mobile communication terminals, electronic notebooks, electronic books, portable multimedia players (PMPs), navigation devices, and ultra mobile PCs (UMPCs). Alternatively, the display device 10, according to an exemplary embodiment, may be applied as a display unit of televisions, laptop computers, computer monitors, electronic billboards, or the Internet of Things (IOTs) devices. Alternatively, the display device 10, according to an exemplary embodiment, may be applied to wearable devices such as smart watches, watch phones, glasses-type displays, and head mounted displays (HMDs). Alternatively, the display device 10, according to an exemplary embodiment, may be applied to a center information display (CID) disposed on an instrument board, a center fascia, or a dashboard of a vehicle, a room mirror display substituting for a side-view mirror of the vehicle, or a display disposed on a rear surface of a front seat as entertainment for a rear seat of the vehicle.

In the present specification, a first direction (e.g., X-axis direction) may be a long side direction of the display device 10, for example, a longitudinal direction of the display device 10. A second direction (e.g., Y-axis direction) may be a short side direction of the display device 10, for example, a transverse direction of the display device 10. A third direction (e.g., Z-axis direction) may be a thickness direction of the display device 10. A corner where a long side in the first direction (e.g., X-axis direction) and a short side in the second direction (e.g., Y-axis direction) meet may be rounded with a predetermined curvature or right-angled.

The display device 10, according to an exemplary embodiment, includes a display panel 300, a display circuit board 310, a display driving circuit 320, a touch driving circuit 330, and an antenna circuit board 340. A connector 341 may be formed on one side of the antenna circuit board 340.

The display panel 300 may be a light emitting display panel including light emitting elements. For example, the display panel 300 may be an organic light emitting display panel using organic light emitting diodes (OLEDs) including organic light emitting layers, a micro light emitting diode display panel using micro light emitting diodes (LEDs), a quantum dot light emitting display panel using quantum dot light emitting diodes including quantum dot light emitting layers, or an inorganic light emitting display panel using inorganic light emitting elements including inorganic semiconductors.

The display panel 300 may be a flexible display panel 300 that may be flexible so as to be easily bent, folded, or rolled to a noticeable extent without cracking or otherwise sustaining damage thereto. For example, the display panel 300 may include a foldable display panel 300 that may be folded and unfolded, a curved display panel 300 whose display surface is curved, a bended display panel 300 whose area other than a display surface is bent, a rollable display panel 300 that may be rolled or unrolled, or a stretchable display panel 300 that may be stretched.

The display panel 300 may include a main area MA, a sub-area SBA protruding from one side of the main area MA, and a protrusion area PA protruding from the other side of the main area MA.

The main area MA may include a display area DA displaying an image and a non-display area NDA, which is a peripheral area of the display area DA. The display area DA may occupy a majority of the main area MA. The display area DA may be disposed at the center of the main area MA. The non-display area NDA may be an area outside the display area DA. The non-display area NDA may at least partially surround the display area DA. The non-display area NDA may be defined as an edge area of the display panel 300. The non-display area NDA may be named a dead space area DS.

The sub-area SBA may protrude from one side of the main area MA in the first direction (e.g., X-axis direction). For example, one side of the main area MA may be a lower side of the main area MA. As illustrated in FIG. 1, a length of the sub-area SBA in the first direction (e.g., X-axis direction) may be smaller than a length of the main area MA in the first direction (e.g., X-axis direction), and a length of the sub-area SBA in the second direction (e.g., Y-axis direction) may be smaller than a length of the main area MA in the second direction (e.g., Y-axis direction), but an exemplary embodiment of the present disclosure is not necessarily limited thereto.

Referring to FIG. 2, the sub-area SBA may be bent, and at least a portion of the sub-area SBA that is bent may be disposed below the display panel 300. In this case, at least a portion of the sub-area SBA may overlap the main area MA of the display panel 300 in the third direction (e.g., Z-axis direction).

Display pads DPD may be disposed at an edge of one side of the sub-area SBA. The edge of one side of the sub-area SBA may be an edge of a lower side of the sub-area SBA. The display circuit board 310 may be attached onto the display pads DPD of the sub-area SBA. The display circuit board 310 may be attached to the display pads DPD of the sub-area SBA using a conductive adhesive such as an anisotropic conductive film or anisotropic conductive paste. The display circuit board 310 may be a flexible printed circuit board (FPCB) that may be bent, a rigid printed circuit board (PCB) that is rigid and is not bent easily, or a composite printed circuit board including both the rigid printed circuit board and the flexible printed circuit board.

The display driving circuit 320 may be disposed on the sub-area SBA of the display panel 300. The display driving circuit 320 may receive control signals and source voltages applied thereto, and generate and output signals and voltages for driving the display panel 300. The display driving circuit 320 may be formed as an integrated circuit (IC).

The touch driving circuit 330 may be disposed on the display circuit board 310. The touch driving circuit 330 may be formed as an integrated circuit. The touch driving circuit 330 may be attached to the display circuit board 310.

The touch driving circuit 330 may be electrically connected to sensor electrodes of a sensor electrode layer of the display panel 300 through the display circuit board 310. The touch driving circuit 330 may output a touch driving signal to each of the sensor electrodes and sense a voltage change according to mutual capacitance of the sensor electrodes.

The sensor electrode layer of the display panel 300 may sense a proximity touch and/or a contact touch. The contact touch may be a person's finger or an object such as a stylus/pen coming into direct contact with a cover window disposed on the sensor electrode layer. The proximity touch may be the person's finger or the object such as the stylus/pen is positioned above the cover window so as to be close to the cover window, such as hovering thereabove.

A power supply unit for supplying driving voltages for driving display pixels of the display panel 300 and the display driving circuit 320 may be additionally disposed on the display circuit board 310. Alternatively, the power supply unit may be integrated with the display driving circuit 320, and in this case, the display driving circuit 320 and the power supply unit may be formed as one integrated circuit.

The protrusion area PA may be an area including an antenna electrode, a feeding line, and/or a ground line of an antenna module for wireless communication. The protrusion area PA may protrude from the other side of the main area MA in the first direction (e.g., X-axis direction). For example, the other side of the main area MA may be an upper side of the main area MA. As illustrated in FIG. 1, a length of the protrusion area PA in the first direction (e.g., X-axis direction) may be smaller than the length of the main area MA in the first direction (e.g., X-axis direction), and a length of the protrusion area PA in the second direction (e.g., Y-axis direction) may be smaller than the length of the main area MA in the second direction (e.g., Y-axis direction), but an exemplary embodiment of the present disclosure is not necessarily limited thereto.

As illustrated in FIG. 2, at least a portion of the protrusion area PA may be bent, and at

least a portion of the protrusion area PA that is bent may be disposed below the display panel 300. In this case, at least a portion of the protrusion area PA may overlap the main area MA of the display panel 300 in the third direction (e.g., Z-axis direction).

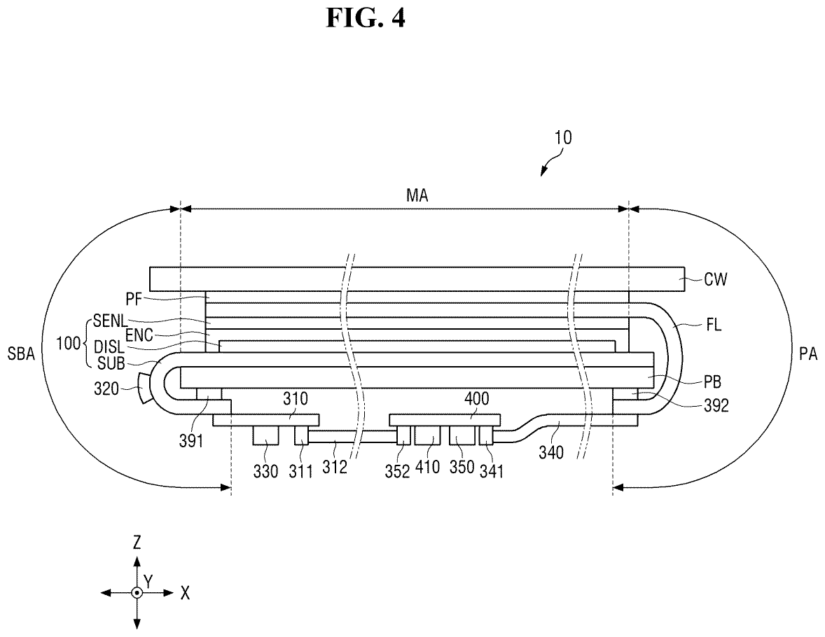

Antenna pads APD may be disposed at an edge of one side of the protrusion area PA. The antenna circuit board 340 may be attached onto the antenna pads APD of the protrusion area PA. The antenna circuit board 340 may be attached onto the antenna pads APD of the protrusion area PA using a conductive adhesive such as an anisotropic conductive film and an anisotropic conductive adhesive. One side of the antenna circuit board 340 may include the connector 341 connected to a main circuit board 400 on which an antenna driving circuit 350 (see FIG. 4) is mounted. The antenna circuit board 340 may be a flexible printed circuit board (FPCB) that may be bent.

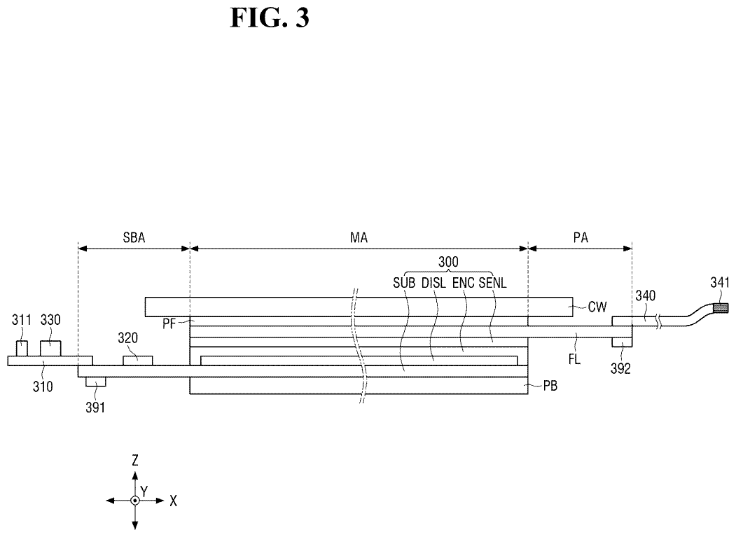

FIGS. 3 and 4 are side views illustrating the display device according to an exemplary embodiment.

Referring to FIGS. 3 and 4, the display panel 300 of the display device 10, according to an exemplary embodiment, may include the following stack structure. The display panel 300 may include a flexible substrate SUB, a display layer DISL disposed on the flexible substrate SUB, an encapsulation layer ENC disposed on the display layer DISL, a sensor electrode layer SENL disposed on the encapsulation layer ENC, a dielectric film FL disposed on the sensor electrode layer SENL, a polarizing layer PF disposed on the dielectric film FL, a cover window CW disposed on the polarizing layer PF, and a lower cover layer PB disposed below the flexible substrate SUB.

The flexible substrate SUB may be made of an insulating material such as a polymer resin. The flexible substrate SUB may be a substrate that may be bent, folded, and rolled.

In the main area MA, the display layer DISL may be disposed on the flexible substrate SUB. The display layer DISL may be a layer including emission areas to display an image. The display layer DISL may include a thin film transistor layer at which thin film transistors are formed and a light emitting element layer at which light emitting elements emitting light are disposed in the emission areas.

Scan lines, data lines, power lines, and the like, for driving the light emitting elements of the emission areas may be disposed in the display area DA of the display layer DISL. A scan driver outputting scan signals to the scan lines, fan-out lines connecting the data lines and the display driving circuit 320 to each other, and the like, may be disposed in the non-display area NDA of the display layer DISL.

The encapsulation layer ENC may be disposed on the display layer DISL. The encapsulation layer ENC may encapsulate the light emitting element layer of the display layer DISL to prevent oxygen or moisture from permeating into the light emitting element layer of the display layer DISL. The encapsulation layer ENC may be disposed on an upper surface and side surfaces of the display layer DISL.

The sensor electrode layer SENL may be disposed on the encapsulation layer ENC. The sensor electrode layer SENL may include sensor electrodes. The sensor electrode layer SENL may sense a touch using sensor electrodes.

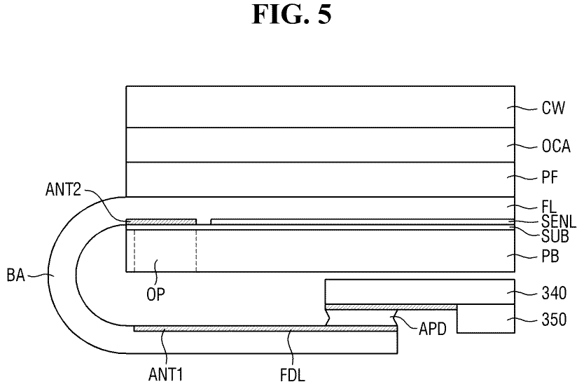

The dielectric film FL may be disposed on the sensor electrode layer SENL. A touch electrode may be disposed in the display area DA of the dielectric film FL. In this case, the sensor electrode layer SENL may be omitted. According to an exemplary embodiment, the protrusion area PA of the display panel 300 may be formed by the dielectric film FL. For example, the dielectric film FL may include a protrusion area PA extending from a portion of the non-display area NDA and bent toward a lower portion of the display panel 300. The protrusion area PA of the dielectric film FL includes a first antenna ANT1 and a second antenna ANT2 as described later with reference to FIG. 5.

The protrusion area PA formed by the dielectric film FL may be attached to a lower surface of the lower cover layer PB by a second adhesive 392. The second adhesive 392 may be a pressure sensitive adhesive.

The polarizing layer PF may be disposed on the dielectric film FL. The polarizing layer PF may include a first base, a linear polarizing plate, a phase retardation film such as a λ/4 plate (quarter-wave plate), and a second base. The first base, the phase retardation film, the linear polarizing plate, and the second base may be sequentially stacked on the sensor electrode layer SENL.

The cover window CW may be disposed on the polarizing layer (e.g., a polarizing film) PF. The cover window CW may be attached onto the polarizing layer PF by a transparent adhesive such as an optically clear adhesive (OCA) film.

The lower cover layer PB may be disposed below the flexible substrate SUB. The lower cover layer PB may be attached to a lower surface of the flexible substrate SUB through an adhesive. The adhesive may be a pressure sensitive adhesive (PSA). The lower cover layer PB may include a light blocker for absorbing light incident from the outside, a buffer for absorbing a shock from the outside, and/or a heat dissipator for efficiently dissipating heat of the display panel 300.

The light blocker blocks transmission of the light to prevent components, for example, the display circuit board 310, disposed below the light blocker from being viewed from above the display panel 300. The light blocker may include a light absorbing material such as a black pigment or a black dye.

The buffer may be disposed below the light blocker. The buffer absorbs an external shock to prevent damage to the display panel 300. The buffer may be formed as a single layer or a plurality of layers. For example, the buffer may be made of a polymer resin such as polyurethane, polycarbonate, polypropylene, or polyethylene or may include a material having elasticity, such as a sponge formed by foaming rubber, a urethane-based material, or an acrylic-based material.

The heat dissipator may be disposed below the buffer. The heat dissipator may include a first heat dissipation layer including graphite, carbon nanotubes, or the like, and a second heat dissipation layer formed as a thin metal film made of copper, nickel, ferrite, or silver that may shield electromagnetic waves and has excellent thermal conductivity.

According to an exemplary embodiment, as illustrated in FIG. 4, the flexible substrate SUB may be bent in the sub-area SBA, and may be disposed below the display panel 300. The sub-area SBA of the flexible substrate SUB may be attached to the lower surface of the lower cover layer PB by a first adhesive 391. The first adhesive 391 may be a pressure sensitive adhesive.

The display circuit board 310 may be attached to the display pads DPD of the sub-area SBA of the flexible substrate SUB using a conductive adhesive such as an anisotropic conductive film or an anisotropic conductive adhesive. The display circuit board 310 may include a connector 311 connected to a flexible circuit board 312. The display circuit board 310 may be connected to a connector 352 of the main circuit board 400 by the flexible circuit board 312.

The touch driving circuit 330 may be disposed on the display circuit board 310. The touch driving circuit 330 may generates touch data according to a change in electrical signal sensed at each of the sensor electrodes of the sensor electrode layer of the display panel 300 and transmit the touch data to a main processor 410 of the main circuit board 400, and the main processor 410 may calculate touch coordinates where a touch has occurred by analyzing the touch data.

The antenna circuit board 340 may be attached to the antenna pads APD of the protrusion area PA using a conductive adhesive such as an anisotropic conductive film and an anisotropic conductive adhesive. The connector 341 of the antenna circuit board 340 may be connected to a connector of the main circuit board 400. The protrusion area PA may be connected to the main circuit board 400 by the antenna circuit board 340.

The main circuit board 400 may be a rigid printed circuit board (PCB) that is rigid and is not bent easily. The main processor 410 and the antenna driving circuit 350 may be disposed on the main circuit board 400.

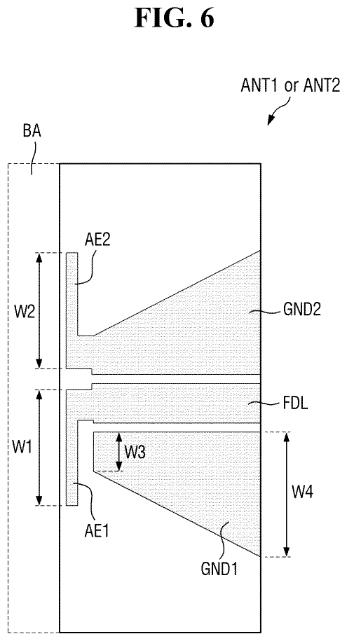

The antenna driving circuit 350 may be electrically connected to antenna electrodes (e.g., AE1 and AE2 in FIG. 6) of the display panel 300 through the antenna circuit board 340. Therefore, the antenna driving circuit 350 may receive electromagnetic wave signals input through the antenna electrodes (e.g., AE1 and AE2 in FIG. 6), and output electromagnetic wave signals to be transmitted to the antenna electrodes (e.g., AE1 and AE2 in FIG. 6). The antenna driving circuit 350 may be formed as an integrated circuit (IC).

The antenna driving circuit 350 may process the electromagnetic wave signals transmitted and received through the antenna electrodes (e.g., AE1 and AE2 in FIG. 6). For example, the antenna driving circuit 350 may change an amplitude of the electromagnetic wave signals received by the antenna electrodes (e.g., AE1 and AE2 in FIG. 6). Alternatively, the antenna driving circuit 350 may change not only an amplitude of the electromagnetic wave signals received by the antenna electrodes, but may also change a phase of the electromagnetic wave signals. The antenna driving circuit 350 may transmit the processed electromagnetic wave signals to a mobile communication module. The mobile communication module may be disposed on the main circuit board 400.

The antenna driving circuit 350 may change an amplitude of electromagnetic wave signals transmitted from the mobile communication module. Alternatively, the antenna driving circuit 350 may change not only an amplitude of the electromagnetic wave signals transmitted from the mobile communication module, but may also change a phase of the electromagnetic wave signals. The antenna driving circuit 350 may transmit the processed electromagnetic wave signals to the antenna electrodes (e.g., AE1 and AE2 in FIG. 6).

FIG. 5 is a schematic cross-sectional view of the display device illustrating a protrusion area PA of a display panel 300 according to an exemplary embodiment. For example, FIG. 5 is a cross-sectional view illustrating a first antenna ANT1 and a second antenna ANT2 disposed in the protrusion area PA.

The display panel 300 may include a flexible substrate SUB, a display layer DISL disposed on the flexible substrate SUB, an encapsulation layer ENC disposed on the display layer DISL, a sensor electrode layer SENL disposed on the display layer DISL, a dielectric film FL disposed on the sensor electrode layer SENL, a polarizing layer PF disposed on the dielectric film FL, a cover window CW disposed on the polarizing layer PF, and a lower cover layer PB disposed below the flexible substrate SUB.

The lower cover layer PB may include a light blocker for absorbing light incident from the outside, a buffer for absorbing a shock from the outside, and/or a heat dissipator for efficiently dissipating heat of the display panel 300.

The antenna circuit board 340 may be attached to the antenna pads APD of the protrusion area PA of the flexible substrate SUB using a conductive adhesive such as an anisotropic conductive film and an anisotropic conductive adhesive.

The antenna driving circuit 350 may be electrically connected to the antenna electrodes (e.g., AE1 and AE2 in FIG. 6) of the display panel 300 through the antenna circuit board 340. Therefore, the antenna driving circuit 350 may receive electromagnetic wave signals input through the antenna electrodes (e.g., AE1 and AE2 in FIG. 6), and output electromagnetic wave signals to be transmitted to the antenna electrodes (e.g., AE1 and AE2 in FIG. 6).

According to an exemplary embodiment, the protrusion area PA of the display panel 300 formed by the dielectric film FL may include a first area in parallel with the non-display area, a bending area extending from the first area and bent toward a rear surface of the display panel 300 to face a side surface direction of the display panel 300, and a second area extending from the bending area and overlapping the first area at a lower portion of the display panel 300.

According to an exemplary embodiment, the first antenna ANT1 is disposed in a portion of the second area of the protrusion area PA corresponding to the non-display area. In addition, the second antenna ANT2 overlapping the first antenna ANT1 is disposed in the first area of the protrusion area PA.

According to an exemplary embodiment, the first antenna ANT1 serves as an antenna radiator contributing to direct radiation. A radiation direction of the first antenna ANT1 may be an upward direction of the display panel 300. To this end, the lower cover layer PB overlapping the first antenna ANT1 may include an opening OP in which the heat dissipator is removed. An antenna signal radiated from the first antenna ANT1 is transferred to the second antenna ANT2 through the opening OP. The second antenna ANT2 may radiate an antenna signal coupled to the signal radiated from the first antenna ANT1. In an exemplary embodiment of the present disclosure, the second antenna ANT2 increases directivity of the signal radiated from the first antenna ANT1 toward the upward direction of the display panel 300 and increase radiation efficiency.

According to an exemplary embodiment, the dielectric film FL may include a material such as polyimide or polyethylene terephthalate (PET), and may have a dielectric constant of about 2.5 to about 3.5.

FIG. 6 is a plan view illustrating a first antenna ANT1 and a second antenna ANT2 according to an exemplary embodiment.

Referring to FIG. 6, the first antenna ANT1, according to an exemplary embodiment, may have a symmetrical dipole antenna structure. The second antenna ANT2 may have the same shape as the first antenna ANT1. For example, the second antenna ANT2 may have a symmetrical dipole antenna structure like the first antenna ANT1. However, the second antenna ANT2 is not necessarily limited to having the same shape as the first antenna ANT1. For example, the second antenna ANT2 may have a patch antenna shape. Hereinafter, it will be mainly described that the first antenna ANT1 and the second antenna ANT2 each have a symmetrical dipole antenna structure, but the present disclosure is not necessarily limited thereto.

The first antenna ANT1 may feed signals in a coplanar waveguide with ground (CPCW) or coplanar waveguide (CPW) structure, and may radiate signals in the form of a wideband dipole antenna through modification of a CPW. For example, the first antenna ANT1 includes a first antenna electrode AE1 extending from a feeding line FDL and a second antenna electrode AE2 spaced apart from the first antenna electrode AE1 and having a length symmetrical to the first antenna electrode AE1. The first antenna electrode AE1 and the second antenna electrode AE2 may face the bending area.

A length W1 of the first antenna electrode AE1 and a length W2 of the second antenna electrode AE2 may be the same as each other.

Ground lines are disposed on both sides of the feeding line FDL, respectively. For example, a first ground line GND1 adjacent to the first antenna electrode AE1 is disposed on one side of the feeding line FDL, and a second ground line GND2 connected to the second antenna electrode AE2 is disposed on the other side of the feeding line FDL. The first ground line GND1 and the second ground line GND2 may have a shape in which they are symmetrical to each other with respect to the power supply line FDL.

The first ground line GND1 may have a shape whose width decreases toward the first antenna electrode AE1. For example, a width of the first ground line GND1 may increase a bandwidth while decreasing from W4 to W3. In addition, a half-wavelength dipole antenna may be constituted by designing the sum of the length W1 of the first antenna electrode AE1 and the length W2 of the second antenna electrode AE2 so as to be close to a half-wavelength. Such a width of the first ground line GND1 may be designed to be in the range of about 3.8 mm to about 5 mm, which is a half-wavelength based on about 28 GHz.

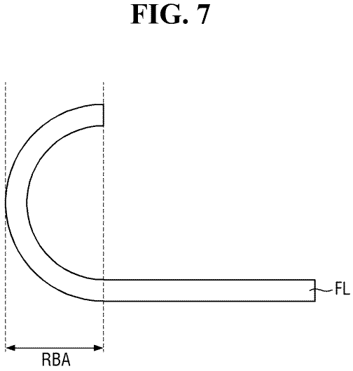

FIG. 7 is a schematic cross-sectional view illustrating a bending area of the protrusion area PA according to an exemplary embodiment.

Referring to FIG. 7, the bending area formed by the dielectric film FL, according to an exemplary embodiment, may have a bending radius RBA in the range of about 0.4 mm to about 1 mm. Such a design of the bending area may serve to increase signal strength of antenna signals radiated from the first antenna ANT1 and the second antenna ANT2 to an upper portion of the display panel 300.

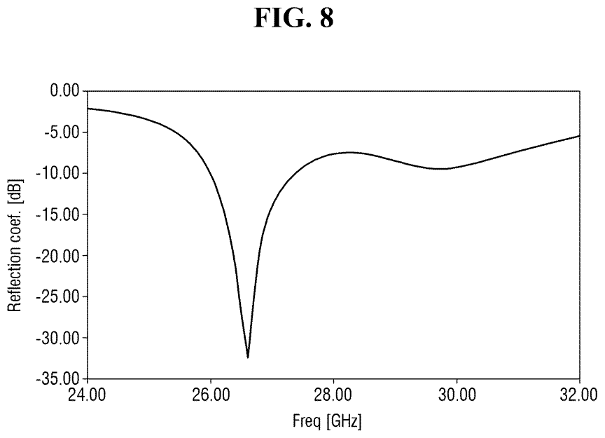

FIG. 8 is a graph illustrating characteristics of the first antenna ANT1 according to an exemplary embodiment. For example, FIG. 8 may be a graph illustrating characteristics of the first antenna ANT1 illustrated in FIG. 6.

Referring to FIG. 8, it may be confirmed that the first antenna ANT1, according to an exemplary embodiment, has a bandwidth of about 25.57 GHz to about 31.68 GHz based on a reflection coefficient of −6 dB.

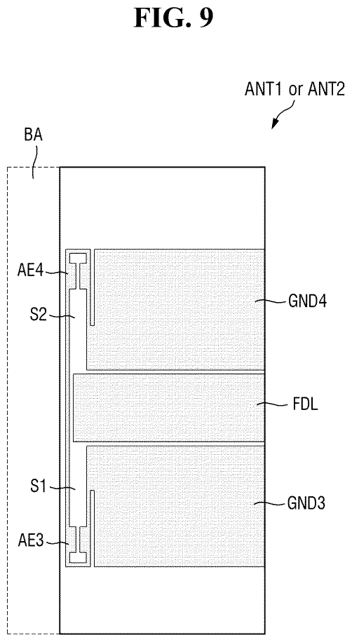

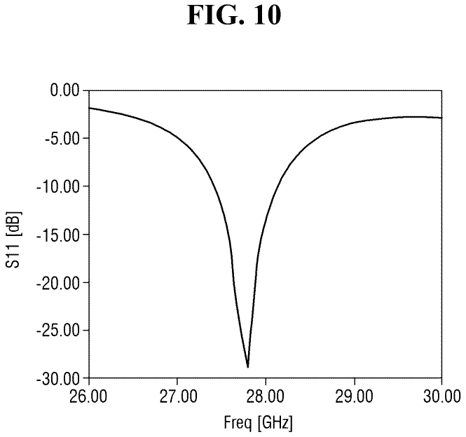

FIG. 9 is a plan view illustrating a first antenna ANT1 and a second antenna ANT2 according to an exemplary embodiment. FIG. 10 is a graph illustrating characteristics of the first antenna ANT1 according to an exemplary embodiment.

Referring to FIG. 9, the first antenna ANT1, according to an exemplary embodiment, may have a symmetrical slot antenna structure. The second antenna ANT2 may have the same shape as the first antenna ANT1. For example, the second antenna ANT2 may have a symmetrical slot antenna structure like the first antenna ANT1. However, the second antenna ANT2 is not necessarily limited to having the same shape as the first antenna ANT1. For example, the second antenna ANT2 may have a patch antenna shape. Hereinafter, it will be mainly described that the first antenna ANT1 and the second antenna ANT2 each have a symmetrical slot antenna structure, but the present disclosure is not necessarily limited thereto.

The first antenna ANT1 may include a third antenna electrode AE3 and a fourth antenna electrode AE4 that are disposed adjacent to one end of a feeding line FDL and extend in both side directions with respect to one end of the feeding line FDL. The third antenna electrode AE3 and the fourth antenna electrode AE4 may have a shape in which they are symmetrical to each other with respect to one end of the power supply line FDL. The third antenna electrode AE3 may be connected to a third ground line GND3 disposed on one side of the feeding line FDL, and the fourth antenna electrode AE4 may be connected to a fourth ground line GND4 disposed on the other side of the feeding line FDL.

The third antenna electrode AE3 may include at least one first slot S1, and the fourth antenna electrode AE4 may include at least one second slot S2. The first slot S1 and the second slot S2 may have a shape in which they are symmetrical to each other with respect to one end of the power supply line FDL.

Referring to FIG. 10, it may be confirmed that the first antenna ANT1, according to an exemplary embodiment, has a bandwidth of about 27.1 GHz to about 28.14 GHz based on a reflection coefficient of −10 dB.

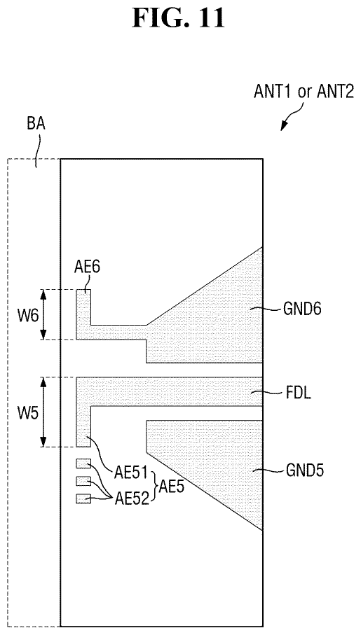

FIG. 11 is a plan view illustrating a first antenna ANT1 and a second antenna ANT2 according to an exemplary embodiment.

Referring to FIG. 11, the first antenna ANT1, according to an exemplary embodiment, may have a Quasi-Yagi structure. The second antenna ANT2 may have the same shape as the first antenna ANT1. For example, the second antenna ANT2 may have a Quasi-Yagi structure like the first antenna ANT1. However, the second antenna ANT2 is not necessarily limited to having the same shape as the first antenna ANT1. For example, the second antenna ANT2 may have a patch antenna shape. Hereinafter, it will be mainly described that the first antenna ANT1 and the second antenna ANT2 each have a Quasi-Yagi structure, but the present disclosure is not necessarily limited thereto.

For example, the first antenna ANT1 includes a fifth antenna electrode AE5 extending from a feeding line FDL and a sixth antenna electrode AE6 spaced apart from the fifth antenna electrode AE5 and having a length asymmetrical to the fifth antenna electrode AE5. The fifth antenna electrode AE5 and the sixth antenna electrode AE6 may face the bending area.

A length W5 of the fifth antenna electrode AE5 and a length W6 of the sixth antenna electrode AE6 may be different from each other. For example, the length W5 of the fifth antenna electrode AE5 is greater than the length W6 of the sixth antenna electrode AE6. In addition, the fifth antenna electrode AE5 includes capacitive electrodes spaced apart from the fifth antenna electrode AE5. For example, the fifth antenna electrode AE5 may include an electrode AE51 connected to the feeding line FDL and electrodes AE52, which are capacitive electrodes spaced apart from the electrode AE51.

Ground lines are disposed on both sides of the feeding line FDL, respectively. For example, a fifth ground line GND5 adjacent to the fifth antenna electrode AE5 is disposed on one side of the feeding line FDL, and a sixth ground line GND6 connected to the sixth antenna electrode AE6 is disposed on the other side of the feeding line FDL. The fifth ground line GND5 and the sixth ground line GND6 may have a shape in which they are symmetrical to each other with respect to the power supply line FDL.

The fifth ground line GND5 may have a shape whose width decreases toward the fifth antenna electrode AE5. The sixth ground line GND6 may have a shape whose width decreases toward the sixth antenna electrode AE6.

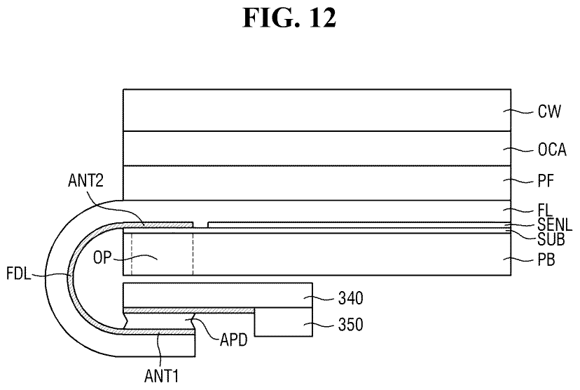

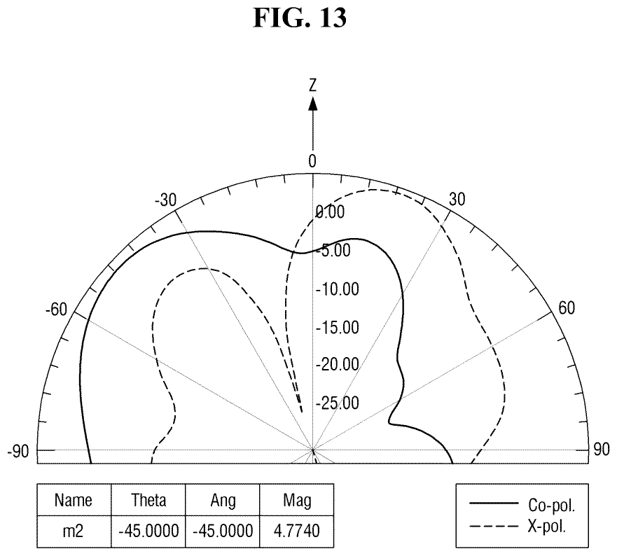

FIG. 12 is a schematic cross-sectional view of a display device illustrating an exemplary embodiment in which a feeding line FDL is disposed in the bending area. FIG. 13 is a diagram illustrating characteristics of the first antenna ANT1 according to an exemplary embodiment.

An exemplary embodiment of FIGS. 12 and 13 is different from an exemplary embodiment of FIG. 5 in that the feeding line FDL connected to the first antenna ANT1 and the second antenna ANT2 is disposed in the bending area. For example, an antenna signal generated from the first antenna ANT1 may be directly applied to the second antenna ANT2 through the feeding line FDL.

Referring to FIG. 13, a metal for housing may be disposed at a lower portion of the display panel 300, and a distance between the first antenna ANT1 and the metal for housing may be defined as “tref”. As used herein, “tref”, which is the distance between the first antenna ANT1 and the metal for the housing, may be a factor affecting a resonant frequency of an antenna.

Assuming that “tref”, which is the distance between the first antenna ANT1 and the metal for housing, is about 2.5 mm, it may be confirmed that a maximum gain of the first antenna ANT1 is about 4.77 dBi.

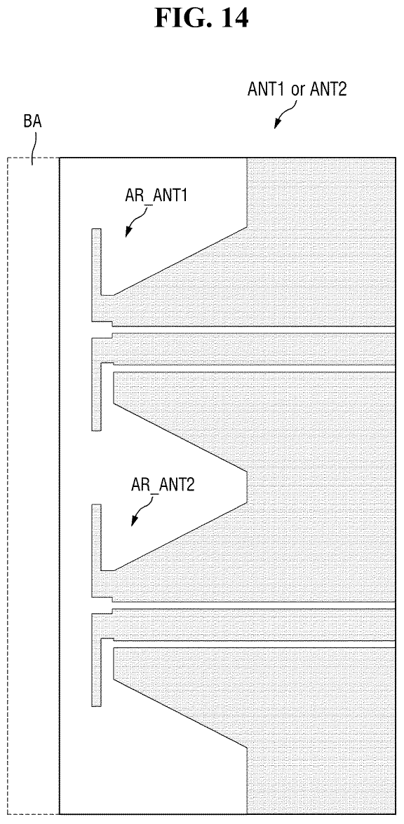

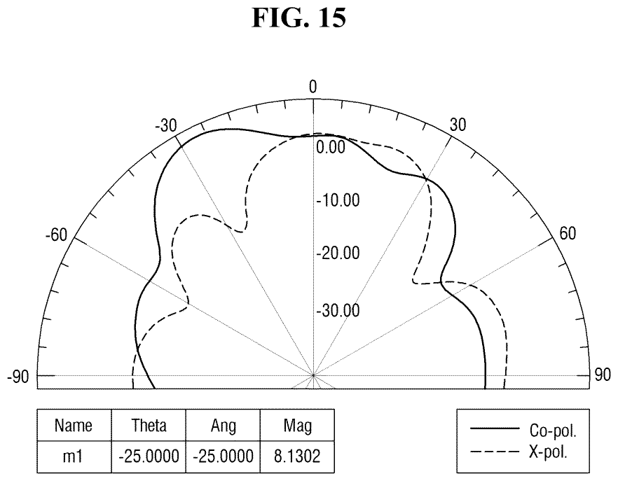

FIG. 14 is a plan view illustrating a first antenna ANT1 and a second antenna ANT2 according to an exemplary embodiment. FIG. 15 is a diagram illustrating characteristics of the first antenna ANT1 according to an exemplary embodiment.

Referring to FIG. 14, the first antenna ANT1, according to an exemplary embodiment, may have an array antenna structure arranged in a 1×N shape (where N is an integer of 2 or more). The second antenna ANT2 may have the same shape as the first antenna ANT1. For example, the second antenna ANT2, according to an exemplary embodiment, may have an array antenna structure arranged in a 1×N shape (where N is an integer of 2 or more) like the first antenna ANT1. However, the second antenna ANT2 is not necessarily limited to having the same shape as the first antenna ANT1. For example, the second antenna ANT2 may have a patch antenna shape. Hereinafter, it will be mainly described that the first antenna ANT1 and the second antenna ANT2 each have an array antenna structure arranged in a 1×N shape (where N is an integer of 2 or more), but the present disclosure is not necessarily limited thereto.

According to various exemplary embodiments, the first antenna ANT1 and the second antenna ANT2 may include array antennas that are disposed at equal intervals, disposed at non-equal intervals, or disposed irregularly.

FIG. 14 illustrates an exemplary embodiment in which a first array antenna AR_ANT1 and a second array antenna AR_ANT2 are disposed side by side as array antennas. In this case, each of the first array antenna AR_ANT1 and the second array antenna AR_ANT2 may have a symmetrical dipole antenna shape described with reference to FIG. 6. An interval between the first array antenna AR_ANT1 and the second array antenna AR_ANT2 may be about 5.8 mm.

Referring to FIG. 15, it may be confirmed that the first antenna ANT1 having the array antenna structure, according to an exemplary embodiment, has an antenna gain improved by about 1.8 dB or more compared to an exemplary embodiment of FIG. 6.

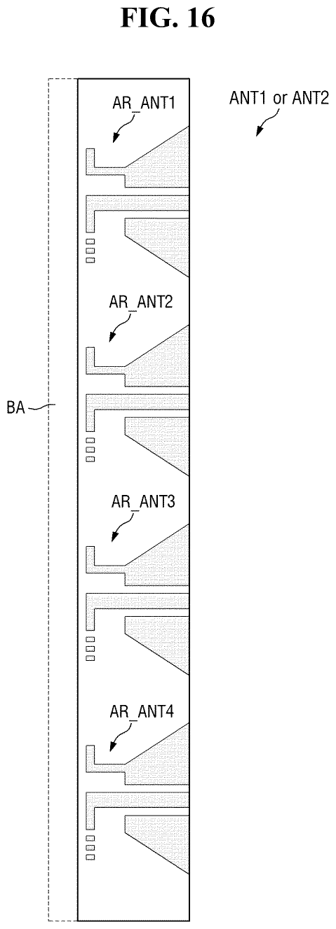

FIG. 16 is a plan view illustrating a first antenna ANT1 and a second antenna ANT2 according to an exemplary embodiment.

An exemplary embodiment of FIG. 16 is different from an exemplary embodiment of FIGS. 14 and 15 in that the first antenna ANT1 includes a first array antenna AR_ANT1, a second array antenna AR_ANT2, a third array antenna AR_ANT3, and a fourth array antenna AR_ANT4 as array antennas. For example, each of the first to fourth array antennas AR_ANT1, AR_ANT2, AR_ANT3, and AR_ANT4 may have a Quasi-Yagi structure described with reference to FIG. 11.

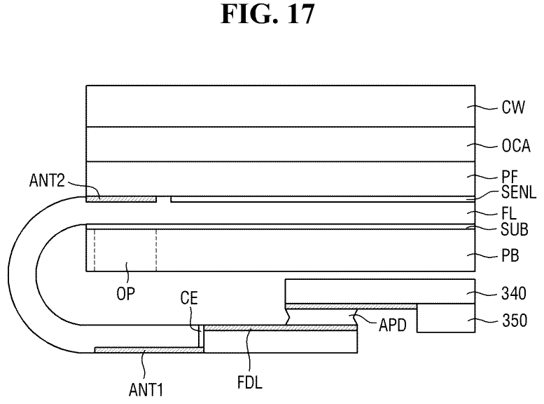

FIG. 17 is a schematic cross-sectional view of a display device illustrating a protrusion area PA of a display panel 300 according to an exemplary embodiment. For example, FIG. 17 is a cross-sectional view illustrating a first antenna ANT1 and a second antenna ANT2 disposed in the protrusion area PA.

An exemplary embodiment of FIG. 17 is different from an exemplary embodiment of FIG. 5 in that the first antenna ANT1 and the second antenna ANT2 are disposed on a front surface of the dielectric film FL. For example, the first antenna ANT1 and the second antenna ANT2 are disposed on a rear surface of the dielectric film FL in an exemplary embodiment of FIG. 5, but may also be disposed on the front surface of the dielectric film FL.

When the first antenna ANT1 and the second antenna ANT2 are disposed on the front of the dielectric film FL, the first antenna ANT1 may be electrically connected to the feeding line FDL through a connection electrode CE penetrating through the dielectric film FL.

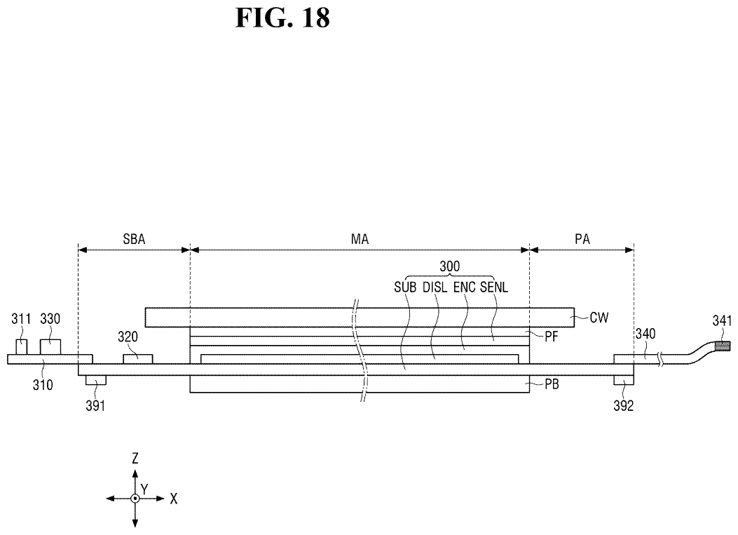

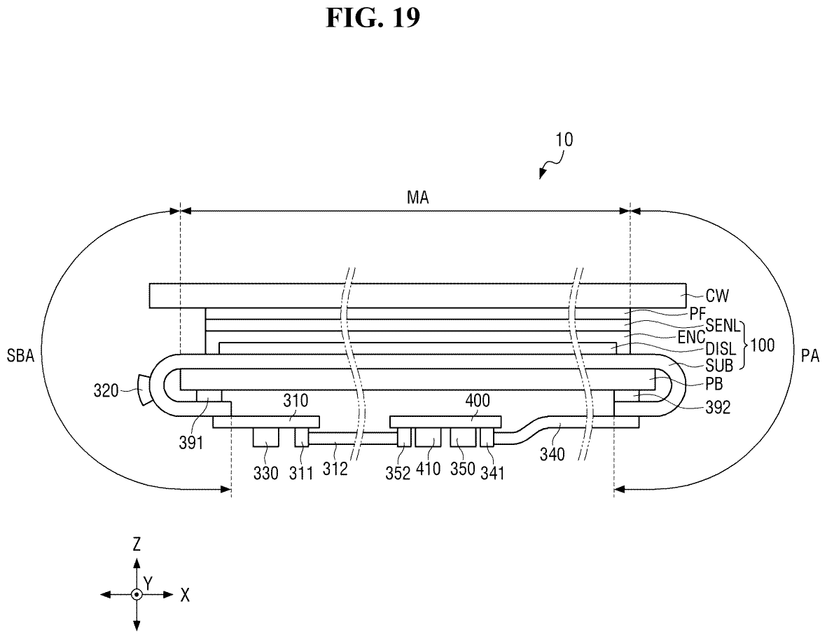

FIGS. 18 and 19 are side views illustrating a display device according to an exemplary embodiment.

An exemplary embodiment of FIGS. 18 and 19 is different from an exemplary embodiment of FIGS. 3 and 4 in that a display panel 300 does not include the dielectric film FL and a first antenna ANT1 and a second antenna ANT2 are formed on a flexible substrate. Thus, to the extent that an element is not described in detail with respect to this figure, it may be understood that the element is at least similar to a corresponding element that has been described elsewhere within the present disclosure.

Referring to FIGS. 18 and 19, the display panel 300 may include a flexible substrate SUB, a display layer DISL disposed on the flexible substrate SUB, an encapsulation layer ENC disposed on the display layer DISL, a sensor electrode layer SENL disposed on the display layer DISL, a polarizing layer PF disposed on the sensor electrode layer SENL, a cover window CW disposed on the polarizing layer PF, and a lower cover layer PB disposed below the flexible substrate SUB.

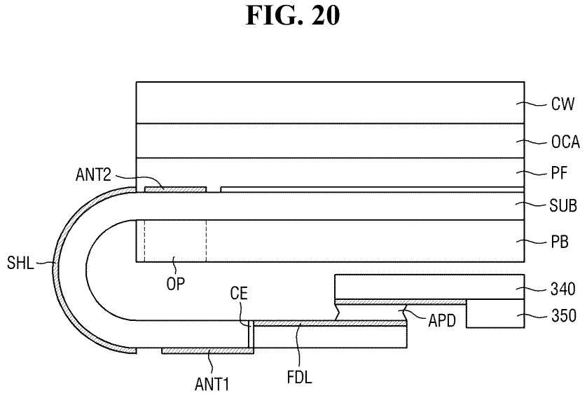

The flexible substrate SUB may include a protrusion area PA extending from a portion of the non-display area NDA and bent toward a lower portion of the display panel 300. The protrusion area PA of the flexible substrate SUB includes a first antenna ANT1 and a second antenna ANT2 as described later with reference to FIGS. 20 to 22.

The protrusion area PA formed by the flexible substrate SUB may be attached to a lower surface of the lower cover layer PB by a second adhesive 392. The second adhesive 392 may be a pressure sensitive adhesive.

FIG. 20 is a schematic cross-sectional view of a display device illustrating a protrusion area PA of a display panel 300 according to an exemplary embodiment. For example, FIG. 20 is a cross-sectional view illustrating the first antenna ANT1 and the second antenna ANT2 according to an exemplary embodiment of FIGS. 18 and 19.

Referring to FIG. 20, the protrusion area PA of the display panel 300 formed by the flexible substrate SUB may include a first area in parallel with the non-display area, a bending area extending from the first area and bent toward a rear surface of the display panel 300 to face a side surface direction of the display panel 300, and a second area extending from the bending area and overlapping the first area at a lower portion of the display panel 300.

According to an exemplary embodiment, the first antenna ANT1 is disposed in a portion of the second area of the protrusion area PA corresponding to the non-display area. In addition, the second antenna ANT2 overlapping the first antenna ANT1 is disposed in the first area of the protrusion area PA.

According to an exemplary embodiment, the first antenna ANT1 serves as an antenna radiator contributing to direct radiation. A radiation direction of the first antenna ANT1 may be an upward direction of the display panel 300. To this end, the lower cover layer PB overlapping the first antenna ANT1 may include an opening OP in which the heat dissipator is removed. An antenna signal radiated from the first antenna ANT1 is transferred to the second antenna ANT2 through the opening OP. The second antenna ANT2 may radiate an antenna signal coupled to the signal radiated from the first antenna ANT1. In an exemplary embodiment of the present disclosure, the second antenna ANT2 increases directivity of the signal radiated from the first antenna ANT1 toward the upward direction of the display panel 300 and increase radiation efficiency.

According to an exemplary embodiment, a shield SHL including a conductive metal may be disposed in the bending area. Such a shield SHL may be segmented from the first antenna ANT1 and the second antenna ANT2. The shield SHL may serve to increase radiation efficiency by increasing directivity of the first antenna ANT1.

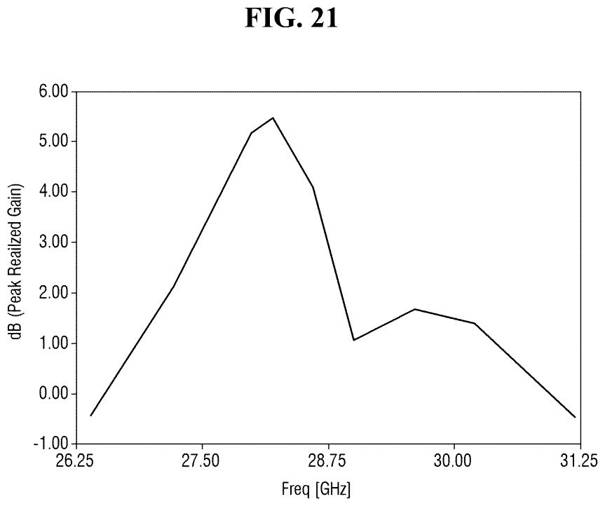

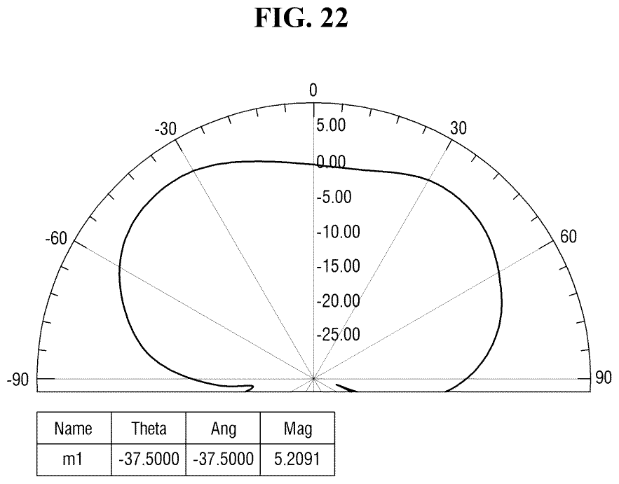

FIGS. 21 and 22 are a graph and a diagram, respectively, illustrating characteristics of the first antenna ANT1 according to an exemplary embodiment. For example, FIGS. 21 and 22 may be a graph and a diagram illustrating characteristics of the first antenna ANT1 illustrated in FIGS. 18 to 20, respectively.

Referring to FIG. 21, it may be confirmed that the first antenna ANT1 has a peak realized gain as illustrated in FIG. 21. In addition, it may be confirmed that the second antenna ANT2 has a radiation pattern along the X-axis direction at a driving frequency of about 28.2 GHz and has a peak gain of about 5.2 dBi, as illustrated in FIG. 22.

With the display device according to exemplary embodiments, it is possible to increase transmission and reception efficiency of wireless communication by disposing antennas to overlap each other in each of the non-display area of the display panel 300 and an extension portion bent from one side of the non-display area and extending to a lower portion of the display panel 300.

In concluding the detailed description, those skilled in the art will appreciate that many variations and modifications can be made to the embodiments described herein without substantially departing from the principles of the present invention.

What is claimed is:

1. A display device, comprising:
a display panel including a display area and a non-display area at least partially surrounding the display area and including a dielectric film including a protrusion area extending from a portion of the non-display area; and
an antenna circuit board connected to the protrusion area,
wherein the protrusion area includes a first area in parallel with the non-display area, a bending area extending from the first area and bent toward a rear surface of the display panel to face a side surface direction of the display panel, and a second area extending from the bending area and overlapping the first area at a lower portion of the display panel, and
wherein the protrusion area further includes:
a first antenna disposed in a portion of the second area corresponding to the non-display area; and
a second antenna overlapping the first antenna in the first area.

2. The display device of claim 1, wherein the display panel has a stack structure that includes:
a flexible substrate;
a lower cover layer disposed below the flexible substrate and including a heat dissipator;
a display layer disposed on the flexible substrate;
a dielectric film disposed on the display layer;
a polarizing film disposed on the dielectric film; and
a cover window disposed on the polarizing film.

3. The display device of claim 2, wherein the lower cover layer includes an opening in which the heat dissipator is removed at a portion thereof overlapping the first antenna and the second antenna.

4. The display device of claim 1, wherein the first antenna and the second antenna each have a symmetrical dipole antenna structure.

5. The display device of claim 1, wherein the first antenna and the second antenna each have a symmetrical slot antenna structure.

6. The display device of claim 1, wherein the first antenna and the second antenna each have a Quasi-Yagi structure.

7. The display device of claim 1, wherein the first antenna and the second antenna are each array antennas arranged in a 1×N shape (where N is an integer of 2 or more).

8. The display device of claim 1, wherein a feeding line connected to the first antenna and the second antenna is disposed in the bending area.

9. The display device of claim 1, wherein a shield including a conductive metal is disposed in the bending area, and
wherein the shield is segmented from the first antenna and the second antenna.

10. The display device of claim 1, wherein the first antenna and the second antenna are each disposed on a front surface of the dielectric film.

11. The display device of claim 1, wherein the first antenna and the second antenna are each disposed on a rear surface of the dielectric film.

12. The display device of claim 1, wherein the dielectric film includes a touch electrode corresponding to the display area.

13. A display device, comprising:
a display panel including a display area and a non-display area at least partially surrounding the display area and including a flexible substrate including a protrusion area extending from a portion of the non-display area; and
an antenna circuit board connected to the protrusion area,
wherein the protrusion area includes a first area in parallel with the non-display area, a bending area extending from the first area and bent toward a rear surface of the display panel to face a side surface direction of the display panel, and a second area extending from the bending area and overlapping the first area at a lower portion of the display panel, and
wherein the protrusion area further includes:
a first antenna disposed in a portion of the second area corresponding to the non-display area; and
a second antenna overlapping the first antenna in the first area.

14. The display device of claim 13, wherein the display panel has a stack structure that includes:
the flexible substrate;
a lower cover layer disposed below the flexible substrate and including a heat dissipator;
a display layer disposed on the flexible substrate;
a polarizing film disposed on the flexible substrate; and
a cover window disposed on the polarizing film.

15. The display device of claim 14, wherein the lower cover layer includes an opening in which the heat dissipator is removed at a portion thereof overlapping the first antenna and the second antenna.

16. The display device of claim 13, wherein the first antenna and the second antenna each have a symmetrical dipole antenna structure.

17. The display device of claim 13, wherein the first antenna and the second antenna each have a symmetrical slot antenna structure.

18. The display device of claim 13, wherein the first antenna and the second antenna each have a Quasi-Yagi structure.

19. The display device of claim 13, wherein the first antenna and the second antenna are array antennas arranged in a 1×N shape (where N is an integer of 2 or more).

20. The display device of claim 13, wherein a feeding line connected to the first antenna and the second antenna is disposed in the bending area.
